(19) United States
(12) Patent Application Publication
(10) Pub. No.: US 2026/0110918 A1
(43) Pub. Date: Apr. 23, 2026

(54) DISPLAY DEVICE, ELECTRONIC DEVICE INCLUDING DISPLAY DEVICE AND METHOD OF MANUFACTURING THE SAME

(71) Applicant: SAMSUNG DISPLAY CO., LTD., YONGIN-SI (KR)

(72) Inventors: Su Bin JUNG, Yongin-si (KR); Hyun Jin CHO, Yongin-si (KR); Eun Kyoung NAM, Yongin-si (KR); Beom Shik KIM, Yongin-si (KR); Young Chan KIM, Yongin-si (KR)

(21) Appl. No.: 19/359,892

(22) Filed: Oct. 16, 2025

(30) Foreign Application Priority Data
Oct. 22, 2024 (KR) 10-2024-0144731

(51) Int. Cl. G02B 30/25; H10K 59/50

(52) U.S. Cl. CPC G02B 30/25; H10K 59/50

(57) ABSTRACT

A display device, an electronic device including the display device and a method of manufacturing the same are provided. The display device includes a display panel and an optic arranged on the display panel. The optic includes a first base substrate, and a second base substrate arranged between the first base substrate and the display panel. A plurality of lenses is arranged between the first base substrate and the second base substrate. Each of the plurality of lenses includes first lens surfaces that are convex in a first direction, second lens surfaces that are convex in a direction opposite to the first direction, and a refractive anisotropic layer arranged between the first lens surfaces and the second lens surfaces. A first resin layer is between the first base substrate and the first lens surfaces. A second resin layer is between the second base substrate and the second lens surfaces. A polarization controller is arranged on the second base substrate and converts a polarization of light incident from the display panel.

This application claims priority under 35 U.S.C. § 119 to Korean Patent Application No. 10-2024-0144731, filed on Oct. 22, 2024 in the Korean Intellectual Property Office, the disclosure of which is incorporated by reference in its entirety herein.

### 1. TECHNICAL FIELD

The present disclosure relates to a display device, an electronic device including the display device, and a method for manufacturing the same.

### 2. DISCUSSION OF RELATED ART

Along with the advancement of communication technology and media, display devices are being applied to an increasing variety of electronic devices to display images in many types of places and environments. For example, a variety of types of display devices such as liquid-crystal display (LCD) devices and organic light-emitting display (OLED) devices are widely used.

A three-dimensional (3D) image display device has recently been developed to provide divided images of the display device in the space in front of the display device using a lens array. A 3D image display device includes a light-field 3D display device that converges light output from each lens of a lens array onto viewing areas where a viewer observes the display device. Accordingly, research is ongoing on a light-field 3D display device that increases the number of viewing areas to display more stereoscopic 3D images. However, crosstalk may occur when the 3D image display device includes numerous viewing areas which decreases the quality of the images displayed.

### SUMMARY

Aspects of the present disclosure provide a display device that reduces crosstalk by reducing spherical aberration of a lens array and reducing light traveling to other areas than viewing areas.

Aspects of the present disclosure also provide a method for fabricating a display device that reduces crosstalk by reducing spherical aberration of a lens array and reducing light traveling to other areas than viewing areas.

According to an embodiment of the present disclosure, a display device includes a display panel. An optic is arranged on the display panel. The optic comprises a first base substrate, and a second base substrate arranged between the first base substrate and the display panel. A plurality of lenses is arranged between the first base substrate and the second base substrate. Each of the plurality of lenses comprises first lens surfaces that are convex in a first direction from the second base substrate towards the first base substrate, second lens surfaces that are convex in a direction opposite to the first direction, and a refractive anisotropic layer arranged between the first lens surfaces and the second lens surfaces and comprising a refractive anisotropic material. A first resin layer is arranged between the first base substrate and the first lens surfaces. A second resin layer is arranged between the second base substrate and the second lens surfaces. A polarization controller is arranged on a surface of the second base substrate. The polarization controller converts a polarization of light incident from the display panel into a first polarized light or a second polarized light.

In an embodiment, a major axis of the refractive anisotropic material may be arranged in a second direction that intersects the first direction. The second direction is an extension direction of the first base substrate and the second base substrate.

In an embodiment, a refractive index of the first resin layer and a refractive index of the second resin layer may be different from a refractive index of the refractive anisotropic layer in a direction of the major axis.

In an embodiment, the refractive index of the first resin layer may be equal to the refractive index of the second resin layer.

In an embodiment, the first base substrate may be in direct contact with the first resin layer, and the second base substrate may be in direct contact with the second resin layer.

In an embodiment, a first curvature of the first lens surfaces may be equal to a second curvature of the second lens surfaces.

In an embodiment, edges of the first lens surfaces may be in direct contact with edges of the second lens surfaces.

In an embodiment, the refractive anisotropic layer may include a first refractive anisotropic layer that is in direct contact with the first lens surfaces and includes a first refractive anisotropic material, and a second refractive anisotropic layer that is in direct contact with the second lens surfaces and includes a second refractive anisotropic material. The first refractive anisotropic material and the second refractive anisotropic material may not be disposed on an interface between the first lens surfaces and the second lens surfaces.

In an embodiment, the interface may be a surface that connects edges of the first lens surfaces with edge of the second lens surfaces.

In an embodiment, the polarization controller may include a first driving electrode arranged under the second base substrate, a second driving electrode spaced apart from the first driving electrode, driving liquid crystals arranged between the first driving electrode and the second driving electrode, and a polarizer arranged under the second driving electrode and in direct contact with an upper surface of the display panel. The polarizer may transmit light vibrating in a second direction perpendicular to the first direction among light incident from the display panel.

In an embodiment, in response to a voltage difference between the first driving electrode and the second driving electrode being less than or equal to a predetermined value, a major axis of the driving liquid crystals may be aligned in the second direction at a lower portion of the driving liquid crystals, and may be aligned in a third direction perpendicular to the second direction towards an upper portion of the driving liquid crystals. The third direction may be perpendicular to the first direction and the second direction.

In an embodiment, the major axis of the driving liquid crystals may be aligned in the first direction in response to the voltage difference between the first driving electrode and the second driving electrode is greater than the predetermined value.

According to an embodiment of the present disclosure, a method for fabricating a display device including a display panel and an optic, includes forming a first resin layer on a first base substrate and imprinting a shape of first lens surfaces on the first resin layer, forming a second resin layer on a second base substrate and imprinting a shape of second lens surfaces on the second resin layer, forming a first alignment film on the first lens surfaces and a second alignment film on the second lens surfaces, forming a first refractive anisotropic layer including a first refractive anisotropic material on the first alignment film and a second refractive anisotropic layer including a second refractive anisotropic material on the second alignment film, coupling the first base substrate on the second base substrate such that edges of the first lens surfaces and edges of the second lens surfaces are in direct contact with each other, and coupling the display panel on a surface of the second base substrate.

In an embodiment, the forming the first alignment film on the first lens surface and the second alignment film on the second lens surface may include performing a rubbing process in a first direction on the first alignment film using a first rubbing cloth, and performing a rubbing process in the first direction or in a second direction opposite to the first direction on the second alignment film using a second rubbing cloth.

In an embodiment, the method may further include forming the optic by bonding a polarization controller on the surface of the second base substrate. The polarization controller may convert a polarization of light incident from the display panel into a first polarized light or a second polarized light.

In an embodiment, a first curvature of the first lens surface may be equal to a second curvature of the second lens surface.

In an embodiment, the first refractive index anisotropic layer and the second refractive index anisotropic layer may include a same material as each other.

In an embodiment, the first refractive index anisotropic layer and the second refractive index anisotropic layer may be oriented in a same direction as each other.

According to an embodiment of the present disclosure, there is provided a method for fabricating a display device including a display panel and an optic, the method including arranging a window on a first base substrate, forming a first resin layer on the window and imprinting a shape of first lens surfaces on the first resin layer, forming a second resin layer on a second base substrate and imprinting a shape of second lens surfaces on the second resin layer, forming a first alignment film on the first lens surfaces and a second alignment film on the second lens surfaces, forming a first refractive anisotropic layer including a first refractive anisotropic material on the first alignment film and a second refractive anisotropic layer including a second refractive anisotropic material on the second alignment film, coupling the first base substrate on the second base substrate such that edges of the first lens surfaces and edges of the second lens surfaces are in direct contact with each other, coupling the display panel on a surface of the second base substrate, and separating the first base substrate from the optic.

In an embodiment, the window may include polyimide.

According to an embodiment of the present disclosure, an electronic device includes a display device. The display device includes a display panel and an optic arranged on the display panel. The optic may include a first base substrate, and a second base substrate arranged between the first base substrate and the display panel. A plurality of lenses is arranged between the first base substrate and the second base substrate. Each of the plurality of lenses includes first lens surfaces that are convex in a first direction from the second base substrate towards the first base substrate, second lens surfaces that are convex in a direction opposite to the first direction, and a refractive anisotropic layer arranged between the first lens surfaces and the second lens surfaces and comprising a refractive anisotropic material. A first resin layer is arranged between the first base substrate and the first lens surfaces. A second resin layer is arranged between the second base substrate and the second lens surfaces. A polarization controller is arranged on a surface of the second base substrate. The polarization controller converts a polarization of light incident from the display panel into a first polarized light or a second polarized light.

These and other aspects and advantages of embodiments of the present disclosure will become immediately apparent to those of ordinary skill in the art upon review of the Detailed Description and Claims.

According to some embodiments of the present disclosure, by using a plurality of lenses including first lens surfaces, second lens surfaces and a refractive anisotropic layer, it is possible to lower the curvature of the lenses compared to existing light-field type of 3D display device. Accordingly, it is possible to suppress the spherical aberration that light passing through the edge of each of the plurality of lenses is excessively refracted and is out of the focus with the light passing through the center of each of the plurality of lenses. In this manner, it is possible to reduce the 3D crosstalk that occurs when light travels to outside the corresponding viewing areas.

In addition, according to some embodiments of the present disclosure, since the curvature of the lenses is lowered, a rubbing process can be easily performed on the edges of the lenses, so that the orientation of the refractive anisotropic material of the refractive anisotropic layer can be increased. Accordingly, light passing through the edges of the first lens surfaces and the edges of the second lens surfaces can accurately propagate to the corresponding viewing areas, so that the 3D crosstalk can be reduced.

It should be noted that effects of the present disclosure are not limited to those described above and other effects of embodiments of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded, perspective view of a display device according to an embodiment of the present disclosure.

FIG. 2 is a perspective view of the display device of FIG. 1 according to an embodiment of the present disclosure.

FIG. 3 is a cross-sectional view of the display device, taken along line I - I′ of FIG. 2, according to an embodiment of the present disclosure.

FIG. 4 is a cross-sectional view of the display device, taken along line I - I′ of FIG. 2, according to an embodiment of the present disclosure.

FIG. 5 is an enlarged view of area A shown in FIG. 3 according to an embodiment of the present disclosure.

FIG. 6 is a cross-sectional view showing in detail the substrate, the thin-film transistor layer, the light-emitting element layer, and the encapsulation layer of FIG. 3 according to an embodiment of the present disclosure.

FIGS. 7 and 8 are views for respectively illustrating a focus of a display device according to a comparative embodiment and according to an embodiment of the present disclosure.

FIG. 9 is a flowchart for illustrating a method for fabricating a display device according to an embodiment of the present disclosure.

FIGS. 10 to 18 are views for illustrating a method of fabricating the display device of FIG. 9 according to embodiments of the present disclosure.

FIG. 19 is an exploded, perspective view of a display device according to an embodiment of the present disclosure.

FIG. 20 is a perspective view of the display device of FIG. 19 according to an embodiment of the present disclosure.

FIG. 21 is a cross-sectional view of the display device, taken along line J - J′ of FIG. 20, according to an embodiment of the present disclosure.

FIG. 22 is a cross-sectional view of the display device, taken along line J - J′ of FIG. 20, according to an embodiment of the present disclosure.

FIG. 23 is a flowchart for illustrating a method for fabricating a display device according to an embodiment of the present disclosure.

FIG. 24 is a diagram illustrating an electronic device according to an embodiment of the present disclosure.

### DETAILED DESCRIPTION OF EMBODIMENTS

Embodiments of the present disclosure will be described more fully hereinafter with reference to the accompanying drawings. Like reference numerals may refer to like elements throughout the specification and the accompanying drawings.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationship between components should be interpreted in a like fashion.

It will be understood that when a component, such as a film, a region, a layer, or an element, is referred to as being “on”, “connected to”, “coupled to”, or “adjacent to” another component, it can be directly on, connected, coupled, or adjacent to the other component, or intervening components may be present. When a component, such as a film, a region, a layer, or an element, is referred to as being “directly on”, “directly connected to”, “directly coupled to”, or “directly adjacent to” another component, no intervening components may be present. It will also be understood that when a component is referred to as “covering” another component, it can be the only component covering the other component, or one or more intervening components may also be covering the other component. Other words use to describe the relationship between elements may be interpreted in a like fashion.

It will be further understood that descriptions of features or aspects within each embodiment are available for other similar features or aspects in other embodiments, unless the context clearly indicates otherwise. Accordingly, all features and structures described herein may be mixed and matched in any desirable manner.

As used herein, the singular forms “a”, “an” and “the” are intended to include the plural forms as well, unless the context clearly indicates otherwise.

When a feature is said to extend, protrude, or otherwise follow a certain direction, it will be understood that the feature may follow said direction in the negative, such as the opposite direction. Accordingly, the feature is not limited to follow exactly one direction, and may follow along an axis formed by the direction, unless the context clearly indicates otherwise.

The present disclosure concerns a display device having an optic which includes first and second base substrates and a plurality of lenses. The plurality of lenses includes first lens surfaces that are convex in a first direction and second lens surfaces that are convex in a direction opposite to the first direction. A first resin layer is arranged between the first base substrate and the first lens surfaces. A second resin layer is arranged between the second base substrate and the second lens surfaces.

Light passing through the second base substrate may be incident on the plurality of lenses from the second resin layer and may be refracted at the second lens surfaces. The light propagating to the first resin layer from the plurality of lenses may then be refracted at the first lens surfaces so that light passing through the edges of the lenses and the center of the lenses all propagate to a single focus. Therefore, the display device provides increased image quality by preventing 3D crosstalk.

The first and second lens surfaces may have a reduced curvature. Therefore, a rubbing process can be more easily performed on the edge of the first and second lens surfaces and the orientation of refractive anisotropic material of the refractive anisotropic layer can be increased.

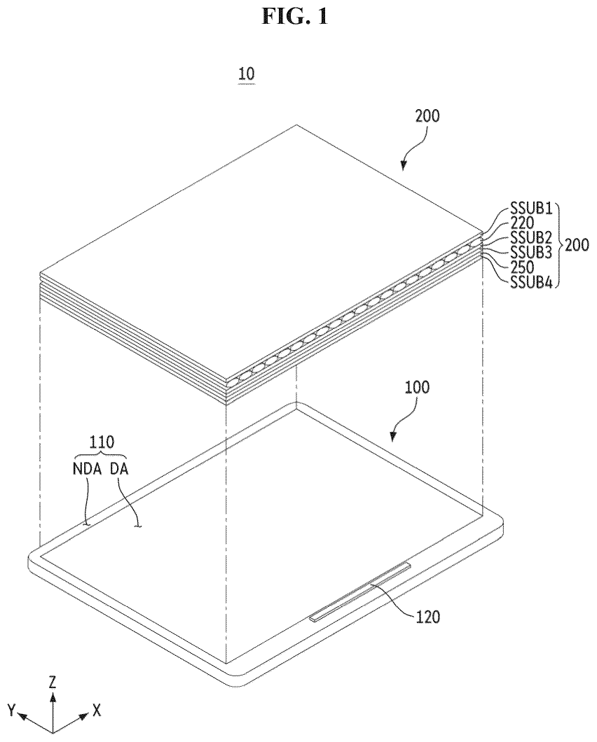

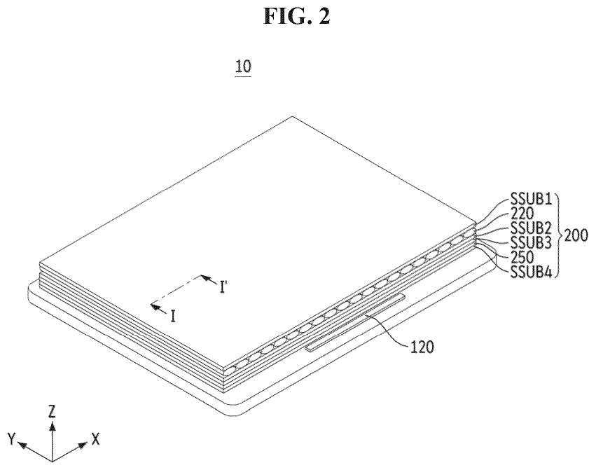

FIG. 1 is an exploded, perspective view of a display device according to some embodiments of the present disclosure. FIG. 2 is a perspective view of the display device of FIG. 1.

In an embodiment, a display device 10 may be implemented as a flat panel display device such as a liquid-crystal display (LCD) device, a field emission display (FED) device, a plasma display panel (PDP) device, a light-emitting diode (LED) device, and an organic light-emitting display (OLED) device.

According to an embodiment of the present disclosure, the display device 10 may be a light-field display device that allows different image information to be seen by a viewers'eyes, respectively, by arranging the optic 200 on the front side of the display module 100. In an embodiment, the light-field display device may generate a 3D stereoscopic image by generating a light field by using the display module 100 that displays a 2D image and the optic 200 that converts the 2D image into a 3D image and displays it to the viewer. As will be described later, the light-field display device allows an image display light generated in each of the pixels in the display module 100 to form a light field directed to a particular direction (e.g., a particular viewing angle and/or a particular viewpoint) by stereoscopic lenses, pinholes, barriers, or the like included in the optic 200. In this manner, 3D stereoscopic image information associated with the particular direction can be provided to the viewer.

The display module 100 may include a display panel 110 and a display driver 120.

In an embodiment, the display panel 110 may include a display area DA and a non-display area NDA. The display area DA may include data lines, scan lines, supply voltage lines, and a plurality of pixels connected to the data lines and scan lines. For example, the scan lines may be extended in the first direction (e.g., an X-axis direction) and be spaced apart from one another in the second direction (e.g., a Y-axis direction). The data lines and the supply voltage lines may be extended in the second direction (e.g., a Y-axis direction) and be spaced from one another in the first direction (e.g., an X-axis direction).

In an embodiment, each pixel (e.g., a unit pixel) formed and arranged on the display panel 110 includes the minimum number of sub-pixels capable of emitting white light. For example, in an embodiment each pixel may include three sub-pixels emitting red, green and blue lights, respectively. Each of the pixels arranged sequentially and repeatedly may be connected to at least one scan line, a data line, and a supply voltage line. Each of the sub-pixels may include thin-film transistors including a driving transistor and at least one switching transistor, a light-emitting element, and a capacitor. When a scan signal is applied from a scan line, each of the pixels receives a data voltage from a data line and supplies a driving current to the light-emitting element according to the data voltage applied to the gate electrode, so that light can be emitted.

Herein, the pixels of the display panel 110 (e.g., the unit pixels) display 2D multi-view images according to the order in which the display driver 120 provides image data. The multi-view images include n view images, where n is a natural number greater than or equal to two. Such n view images are generated by capturing images of an object with n cameras spaced apart from one another by the distance between a person's eyes.

The display panel 110 may display multi-view images in units of n pixels during an image display period. For example, in an embodiment the display panel 110 may display multi-view images in units of two pixels. For example, two pixels of the display panel 110 may display a multi-view image including two view images. In particular, the display panel 110 may display a multi-view image in units of time-division frames (e.g., sub-frames) according to the time-division driving of the display driver 120. Multi-view images may be displayed in units of two pixels for each time-division frame. A time-division frame is a period that divides one frame into ½ or ⅓ sub-frames.

The non-display area NDA may be arranged at the edge of the display panel 110 to surround the display area DA (e.g., in a plan view). In an embodiment, the non-display area NDA may include a scan driver that applies scan signals to scan lines, and pads connected to the display driver 120. For example, the display driver 120 may be arranged on one side of the non-display area NDA, and the pads may be arranged on one edge of the non-display area NDA on which the display driver 120 is arranged.

The display driver 120 may output control signals and image data voltages for driving the display panel 110 in units of at least one frame or at least one time-division frame (e.g., a sub-frame). For example, the display driver 120 may supply image data voltages to the data lines in units of at least one time-division frame (e.g., a sub-frame). The display driver 120 supplies supply voltage to the supply voltage line, and may supply scan control signals to the scan driver.

In an embodiment, the display driver 120 may be implemented as an integrated circuit (IC) and may be arranged in the non-display area NDA of the display panel 110 by a chip on glass (COG) technique, a chip on plastic (COP) technique, or an ultrasonic bonding. For another example, the display driver 120 may be mounted on a circuit board and connected to the pads of the display panel 110.

In an embodiment, the optic 200 includes a first base substrate SSUB1, a second base substrate SSUB2, a plurality of lenses 220 arranged between the first base substrate SSUB1 and the second base substrate SSUB2, a third base substrate SSUB3 and a fourth base substrate SSUB4 arranged under the second base substrate SSUB2, and a polarization controller 250 arranged between the third base substrate SSUB3 and the fourth base substrate SSUB4.

The optic 200 may be arranged on the front side of the display panel 110 or the display module 100. In an embodiment, the optic 200 may be attached to one surface of the display panel 110 or the display module 100 through an adhesive. The optic 200 may be attached to the front surface of the display module 100 by a panel bonding apparatus.

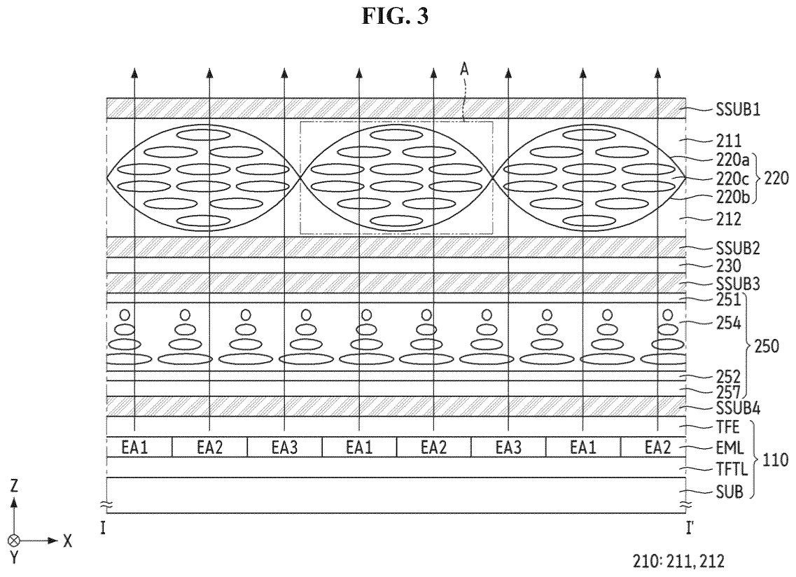

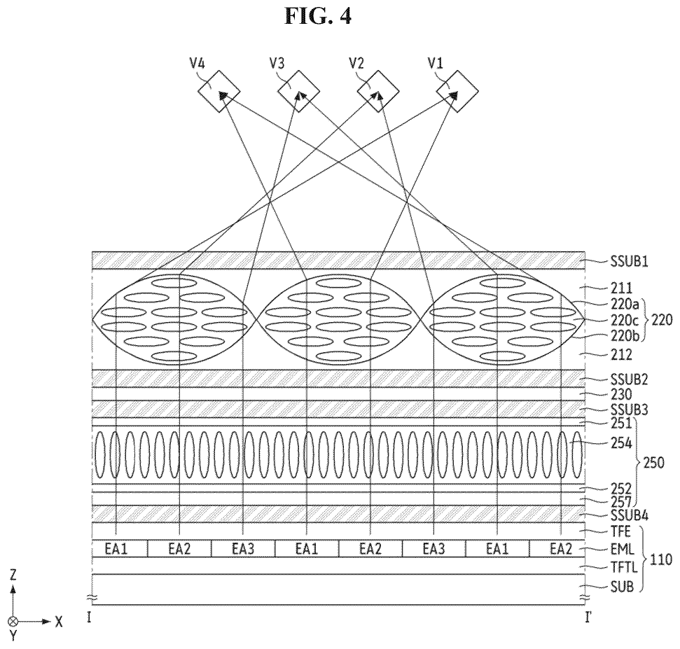

FIG. 3 is a cross-sectional view of the display device, taken along line I - I′ of FIG. 2. FIG. 4 is a cross-sectional view of the display device, taken along line I - I′ of FIG. 2.

FIG. 3 shows an example of a display device in a 2D image display period. FIG. 4 shows an example of the display device in a 3D image display period.

Referring to FIG. 3, in an embodiment the display panel 110 includes the substrate SUB, the thin-film transistor layer TFTL, the light-emitting element layer EML, and the encapsulation layer TFE.

The substrate SUB may have rigidity to support an element formed on the substrate SUB. For example, in an embodiment the substrate SUB may be a glass substrate or a plastic substrate such as polyethylene terephthalate (PET).

The thin-film transistor layer TFTL may be arranged on the substrate SUB (e.g., disposed directly thereon in the Z-axis direction). The thin-film transistor layer TFTL may adjust the brightness of the display device 10. The thin-film transistor layer TFTL may include transistors.

The light-emitting element layer EML may be arranged on the thin-film transistor layer TFTL (e.g., disposed directly thereon in the Z-axis direction). In an embodiment, the light-emitting element layer EML may include first to third light-emitting areas EA1, EA2 and EA3. The first to third light-emitting areas EA1, EA2 and EA3 may be arranged sequentially and repeatedly (e.g., in the X-axis direction).

The encapsulation layer TFE may be arranged on the light-emitting element layer EML (e.g., disposed directly thereon in the Z-axis direction). In an embodiment, the encapsulation layer TFE includes at least one inorganic film and at least one organic film for encapsulating the light-emitting element layer EML.

In an embodiment, the optic 200 may include first to fourth base substrates SSUB1 to SSUB4, a plurality of lenses 220 arranged between the first base substrate SSUB1 and the second base substrate SSUB2 (e.g., in the Z-axis direction), a resin layer 210 arranged between the first base substrate SSUB1 and the plurality of lenses 220 and between the second base substrate SSUB2 and the plurality of lenses 220, a polarization controller 250 arranged between the third base substrate SSUB3 and the fourth base substrate SSUB4 (e.g., in the Z-axis direction), and a coupling portion 230 that couples the second base substrate SSUB2 with the third base substrate SSUB3.

The first to fourth base substrates SSUB1 to SSUB4 may include a material that allows light to pass through, such as glass and plastic.

The fourth base substrate SSUB4 may be arranged on the display panel 110 (e.g., disposed directly thereon in the Z-axis direction). The lower surface of the fourth base substrate SSUB4 may be in direct contact with the upper surface of the display panel 110.

The polarization controller 250 may be arranged on the fourth base substrate SSUB4 (e.g., disposed directly thereon in the Z-axis direction). In an embodiment, the polarization controller 250 may include a first driving electrode 251, a second driving electrode 252, driving liquid crystal 254, and a polarizer 257

The first driving electrode 251 may be arranged on the lower side of the third base substrate SSUB3 (e.g., disposed directly thereon in a direction opposite to the Z-axis direction). The upper surface of the first driving electrode 251 may be in direct contact with the lower surface of the third base substrate SSUB3. The first driving electrode 251 may receive a driving voltage from the display driver 120.

The second driving electrode 252 may be arranged above the display panel 110 (e.g., disposed directly thereon in the Z-axis direction). The second driving electrode 252 may be arranged in parallel to the first driving electrode 251. The shape of the second driving electrode 252 may conform to the shape of the first driving electrode 251.

The polarizer 257 may be arranged under the second driving electrode 252 (e.g., disposed directly thereunder in a direction opposite to the Z-axis direction). The polarizer 257 may be arranged on the display panel 110 (e.g., disposed directly thereon in the Z-axis direction). The lower surface of the polarizer 257 may be in direct contact with the upper surface of the fourth base substrate SSUB4. The polarizer 257 may transmit light vibrating in a particular direction and block light vibrating in a direction different from the direction. In the following description, the polarizer 257 passes light vibrating in the first direction (e.g., the X-axis direction), such as a first linear polarization direction for convenience of illustration.

The driving liquid crystal 254 may be arranged between the first driving electrode 251 and the second driving electrode 252 (e.g., in the Z-axis direction). In an embodiment, the driving liquid crystal 254 may include a plurality of liquid crystals that are birefringent material. The arrangement of the driving liquid crystal 254 may vary depending on the voltage difference between the first driving electrode 251 and the second driving electrode 252.

Referring to FIG. 3, in an embodiment, in response to the driving control of the display driver 120, the polarization controller 250 may convert the light incident on the path in the first linear polarization direction to light on the path in the second linear polarization direction (e.g., light vibrating in the Y-axis direction) to pass it during the 2D image display period.

For example, the display driver 120 may apply a first driving voltage equally to the first driving electrode 251 and the second driving electrode 252.

If the voltage difference between the first driving electrode 251 and the second driving electrode 252 is less than or equal to a predetermined value, the major axis of the liquid crystals may be aligned in the first direction (e.g., the X-axis direction) at the lower portion of the driving liquid crystal 254. The major axis of the liquid crystals may be aligned in the second direction (e.g., the Y-axis direction) at the upper portion of the driving liquid crystal 254. The major axis of the liquid crystals may gradually change between the upper and lower portions of the driving liquid crystal 254. For example, in an embodiment the driving liquid crystal 254 may be TN (twisted nematic) liquid crystal.

Light in the first linear polarization direction may be incident on the driving liquid crystal 254 from the polarizer 257. The light in the first linear polarization direction may be converted into light in different linear polarization directions along the liquid crystals with gradually changing major axis. Accordingly, the light in the first linear polarization direction may be converted into light in the second linear polarization direction by the driving liquid crystal 254.

On the other hand, referring to FIG. 4, in an embodiment during the 3D image display period, in response to the driving control of the display driver 120, the polarization controller 250 may pass the light incident on the path in the first linear polarization direction through the path in the first linear polarization direction as it is without changing the light in different linear polarization directions.

If the voltage difference between the first driving electrode 251 and the second driving electrode 252 is greater than the predetermined value, all liquid crystals of the driving liquid crystal 254 may be aligned in the third direction (Z-axis direction).

Like in FIG. 3, light in the first linear polarization direction may be incident on the driving liquid crystal 254 from the polarizer 257. However, unlike FIG. 3, in FIG. 4, light in the first linear polarization direction may pass through the liquid crystals having a major axis that is aligned in the third direction (e.g., the Z-axis direction) as it is. For example, the incident light in the first linear polarization direction may be output while maintaining the first linear polarization direction even after passing through the driving liquid crystal 254.

The third base substrate SSUB3 may be arranged on the polarization controller 250 (e.g., disposed directly thereon in the Z-axis direction). The lower surface of the third base substrate SSUB3 may be in direct contact with the upper surface of the polarization controller 250.

The coupling portion 230 may be arranged on the third base substrate SSUB3 (e.g., disposed directly thereon in the Z-axis direction). The coupling portion 230 may couple the second base substrate SSUB2 with the third base substrate SSUB3. In an embodiment, the coupling portion 230 may include a transparent adhesive material such as an optically clear adhesive (OCA) film and an optically clear resin (OCR).

The second base substrate SSUB2 may be arranged on the coupling portion 230 (e.g., disposed directly thereon in the Z-axis direction). A second resin layer 212 may be arranged on the second base substrate SSUB2 (e.g., disposed directly thereon in the Z-axis direction).

In an embodiment, the resin layer 210 may include a first resin layer 211 and the second resin layer 212. In an embodiment, the first resin layer 211 and the second resin layer 212 may include at least one of an acrylic resin, an epoxy resin, a phenolic resin, a polyamide resin, and a polyimide resin. The refractive index of the first resin layer 211 may be equal to the refractive index of the second resin layer 212. The first resin layer 211 and the second resin layer 212 may include a same material as each other.

A plurality of lenses 220 may be arranged on the second resin layer 212. In an embodiment, the plurality of lenses 220 may include first lens surfaces 220a that are convex in the third direction (e.g., the Z-axis direction), second lens surfaces 220b that are convex in the direction opposite to the third direction (e.g., a direction opposite to the Z-axis direction), and a refractive anisotropic layer 220c. For example the first lens surfaces 220a may be convex in a direction from the first second base substrate SSUB2 towards the first base substrate SSUB1. The second lens surfaces 220b may be convex in an opposite direction which is a direction from the first base substrate SSUB1 towards the second base substrate SSUB2.

The first lens surfaces 220a may be interfaces between the plurality of lenses 220 and the first resin layer 211. The second lens surfaces 220b may be interfaces between the plurality of lenses 220 and the second resin layer 212. A first curvature of the first lens surfaces 220a may be equal to a second curvature of the second lens surfaces 220b. For example, the first curvature and the second curvature may be determined based on the number of viewing areas and the viewing angle at which 3D images are displayed in a 3D image display mode. The edges of the first lens surfaces 220a may be in direct contact with the edges of the second lens surfaces 220b.

The refractive anisotropic layer 220c may be arranged between the first lens surfaces 220a and the second lens surfaces 220b. The refractive anisotropic layer 220c may include a refractive anisotropic material. For example, in an embodiment the refractive anisotropic layer 220c may include liquid crystals, reactive mesogens (RM), etc. The refractive anisotropic materials may be arranged in a direction crossing the third direction (e.g., the Z-axis direction). For example, the refractive anisotropic materials may be arranged in the first direction (e.g., the X-axis direction) which is an extension direction of the first base substrate SSUB1 and the second base substrate SSUB2.

Referring to FIG. 3, the plurality of lenses 220 may pass the light as it is which has been converted to a path in the second linear polarization direction through the polarization controller 250 (e.g., light vibrating in the Y-axis direction) during the 2D image display period.

On the other hand, referring to FIG. 4, during the 3D image display period, when light is incident on the plurality of lenses 220 via a path in the first linear polarization direction through the polarization controller 250, the light in the first linear polarization direction is refracted towards predetermined viewing areas V1 to V4 by the arrangement of lens forming material or birefringent materials, such that a 3D image is displayed.

For example, the plurality of lenses 220 passes the light incident on the path in the second linear polarization direction as it is via the path in the second linear polarization direction. The plurality of lenses 220 refracts the light incident on the path in the first linear polarization direction to output it to the predetermined viewing areas V1 to V4. Accordingly, a 3D stereoscopic image is displayed through the plurality of lenses 220 during the 3D image display period.

The first resin layer 211 may be arranged on the plurality of lenses 220. The interface between the plurality of lenses 220 and the first resin layer 211 may be the first lens surfaces 220a. The first lens surfaces 220a may be curved surfaces that are convex in the third direction (e.g., the Z-axis direction).

The refractive index of the resin layer 210 may be equal to the refractive index of the minor axis direction of the refractive anisotropic material included in the plurality of lenses 220. The refractive index of the first resin layer 211 and the second resin layer 212 may be different from a refractive index of the refractive anisotropic layer 220c in a direction of the major axis (e.g., the X-axis direction). Accordingly, depending on the polarization direction of the light passing through the plurality of lenses 220, refraction may or may not occur at the interface between the plurality of lenses 220 and the resin layer 210.

For example, when the polarization direction of the light passing through the plurality of lenses 220 coincides with the major axis direction (e.g., the X-axis direction) of the refractive anisotropic material included in the plurality of lenses 220, refraction may occur at the interface between the plurality of lenses 220 and the resin layer 210.

On the other hand, when the polarization direction of the light passing through the plurality of lenses 220 coincides with the minor axis direction (e.g., the Y-axis direction) of the refractive anisotropic material included in the plurality of lenses 220, no refraction may occur at the interface between the plurality of lenses 220 and the resin layer 210.

The first base substrate SSUB1 may be arranged on the first resin layer 211 (e.g., disposed directly thereon in the Z-axis direction). No electrode may be arranged between the first base substrate SSUB1 and the second base substrate SSUB2.

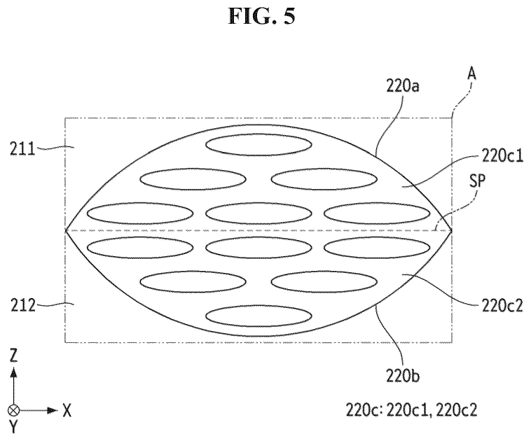

FIG. 5 is an enlarged view of area A shown in FIG. 3.

Referring to FIG. 5, in an embodiment the refractive anisotropic layer 220c may include a first refractive anisotropic layer 220c1 and a second refractive anisotropic layer 220c2.

The first refractive anisotropic layer 220c1 may be in direct contact with the first lens surface 220a. The first refractive anisotropic layer 220c1 may include a first refractive anisotropic material. For example, the first refractive anisotropic material may be arranged in the first direction (e.g., the X-axis direction).

The second refractive anisotropic layer 220c2 may be in direct contact with the second lens surface 220b. The second refractive anisotropic layer 220c2 may include a second refractive anisotropic material. For example, the second refractive anisotropic material may be arranged in the first direction (X-axis direction).

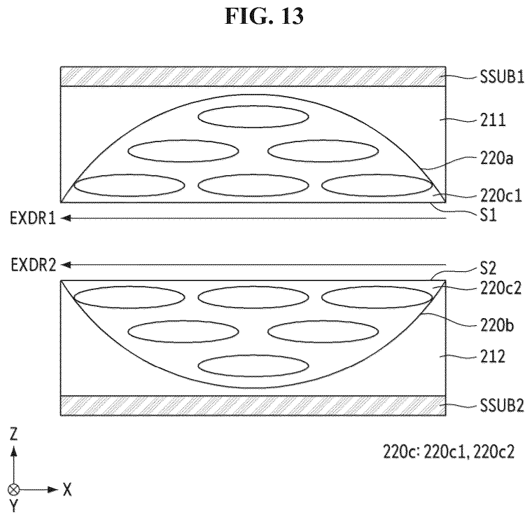

In fabricating the optic 200, a first refractive anisotropic layer 220c1 and a second refractive anisotropic layer 220c2 may be formed separately, and then the first refractive anisotropic layer 220c1 and the second refractive anisotropic layer 220c1 may be attached together, thereby forming a plurality of lenses 220. The first refractive anisotropic layer 220c1 and the second refractive anisotropic layer 220c2 may be in direct contact with each other at an interface SP. The interface SP may be a surface connecting an edge of the first lens surface 220a with an edge of the second lens surface 220b. For example, the interface SP may extend longitudinally in the first direction (e.g., the X-axis direction). In an embodiment, the first refractive anisotropic material and the second refractive anisotropic material may not be disposed on the interface SP. The interface SP will be described later in more detail with reference to FIG. 13.

The interface SP may be a surface where the lower surface S1 (see FIG. 13) of the first refractive anisotropic layer 220c1 and the upper surface S2 (see FIG. 13) of the second refractive anisotropic layer 220c2 come into direct contact with each other.

Since the first refractive anisotropic material of the first refractive anisotropic layer 220c1 and the second refractive anisotropic material of the second refractive anisotropic layer 220c1 are transparent, once the lower surface S1 of the first refractive anisotropic layer 220c1 and the upper surface S2 of the second refractive anisotropic layer 220c2 are attached together, the interface SP may not be seen. In this instance, the interface SP may be defined as an imaginary surface connecting edges of the first lens surface 220a with edges of the second lens surface 220b and extending in a line (e.g., in the X-axis direction). The first refractive anisotropic material and the second refractive anisotropic material may not be disposed on the interface SP, and the first refractive anisotropic material and the second refractive anisotropic material may be the same as each other.

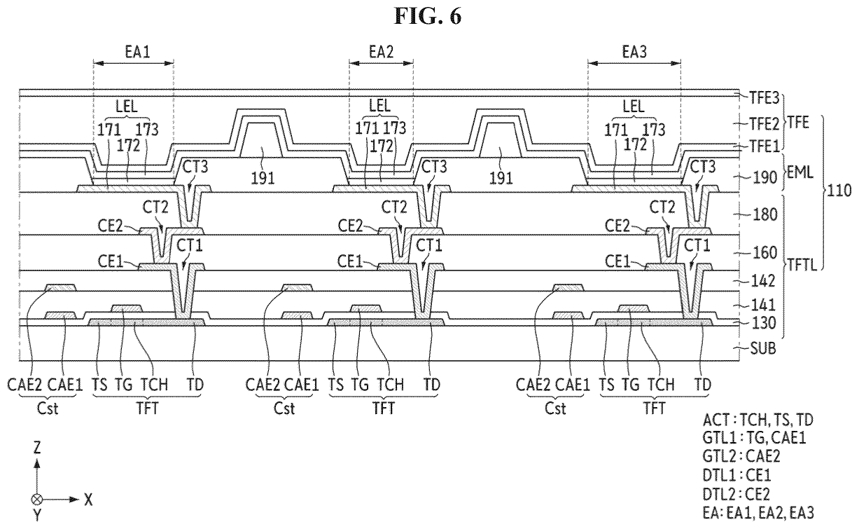

FIG. 6 is a cross-sectional view showing in detail the substrate, the thin-film transistor layer, the light-emitting element layer, and the encapsulation layer of FIG. 3.

Referring to FIG. 6, in an embodiment the display panel 110 may include the substrate SUB, the thin-film transistor layer TFTL, the light-emitting element layer EML, and the encapsulation layer TFE.

In an embodiment, the thin-film transistor layer TFTL includes an active layer ACT, a first gate layer GTL1, a second gate layer GTL2, a first data metal layer DTL1, and a second data metal layer DTL2. In addition, in an embodiment the thin-film transistor layer TFTL includes a gate insulator 130, a first interlayer dielectric film 141, a second interlayer dielectric film 142, a first planarization film 160, and a second planarization film 180. The thin-film transistor layer TFTL includes a plurality of thin-film transistors TFT. Each of the thin-film transistors TFT includes a channel TCH, a gate electrode TG, a first electrode TS and a second electrode TD.

The active layer ACT may be arranged on the substrate SUB (e.g., disposed directly thereon in the Z-axis direction). In an embodiment, the active layer ACT may include silicon semiconductor such as polycrystalline silicon, monocrystalline silicon and low-temperature polycrystalline silicon, or may include oxide semiconductor.

The active layer ACT may include a channel TCH, a first electrode TS and a second electrode TD of each of the thin-film transistors TFT. The channel TCH may be a region overlapping with the gate electrode TG of the thin-film transistor TFT in the third direction (e.g., the Z-axis direction), which is the thickness direction of the substrate SUB. The first electrode TS may be arranged on one side of the channel TCH, and the second electrode TD may be arranged on the opposite side of the channel TCH. The first electrode TS and the second electrode TD may be regions that do not overlap with the gate electrode TG in the third direction (Z-axis direction). The first electrode TS and the second electrode TD may be regions having conductivity by doping ions in a silicon semiconductor or an oxide semiconductor.

The gate insulator 130 may be arranged on (e.g., directly thereon) the active layer ACT. In an embodiment, the gate insulator 130 may be formed of an inorganic layer, for example, a silicon nitride layer, a silicon oxynitride layer, a silicon oxide layer, a titanium oxide layer, or an aluminum oxide layer.

The first gate layer GTL1 may be arranged on the gate insulator 130 (e.g., disposed directly thereon in the Z-axis direction). The first gate layer GTL1 may include the gate electrode TG of each of the thin-film transistors TFT and a first capacitor electrode CAE1. In an embodiment, the first gate layer GTL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 141 may be arranged over (e.g., directly thereon) the first gate layer GTL1. In an embodiment, the first interlayer dielectric film 141 may be formed of an inorganic layer, for example, a silicon nitride layer, a silicon oxynitride layer, a silicon oxide layer, a titanium oxide layer, or an aluminum oxide layer.

The second gate layer GTL2 may be arranged on the first interlayer dielectric film 141 (e.g., disposed directly thereon in the Z-axis direction). The second gate layer GTL2 may include a second capacitor electrode CAE2. The second capacitor electrode CAE2 may overlap the first capacitor electrode CAE1 in the third direction (e.g., the Z-axis direction). The capacitor Cst may include a first capacitor electrode CAE1 and a second capacitor electrode CAE2. In an embodiment, the second gate layer GTL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second interlayer dielectric film 142 may be arranged over the second gate layer GTL2 (e.g., disposed directly thereon in the Z-axis direction). In an embodiment, the second interlayer dielectric film 142 may be formed of an inorganic layer, for example, a silicon nitride layer, a silicon oxynitride layer, a silicon oxide layer, a titanium oxide layer, or an aluminum oxide layer.

The first data metal layer DTL1 including a first connection electrode CE1 may be arranged on the second interlayer dielectric film 142 (e.g., disposed directly thereon in the Z-axis direction). The first connection electrode CE1 may be connected to the first electrode TS or the second electrode TD of the thin-film transistor TFT through a first contact hole CT1 penetrating the gate insulator 130, the first interlayer dielectric film 141 and the second interlayer dielectric film 142. In an embodiment, the first data metal layer DTL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first planarization film 160 may be arranged on (e.g., directly thereon) the first data metal layer DTL1 to provide a flat surface over the level differences of the active layer ACT, the first gate layer GTL1, the second gate layer GTL2, and the first data metal layer DTL1. In an embodiment, the first planarization film 160 may be formed of an organic layer such as an acryl resin, an epoxy resin, a phenolic resin, a polyamide resin and a polyimide resin.

A second data metal layer DTL2 may be arranged on the first planarization film 160 (e.g., disposed directly thereon in the Z-axis direction). The second data metal layer DTL2 may include a second connection electrode CE2. In an embodiment, the second connection electrode CE2 may be connected to the first connection electrode CE1 through a second contact hole CT2 penetrating the first planarization film 160. In an embodiment, the second data metal layer DTL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization film 180 may be arranged on (e.g., disposed directly thereon) the second data metal layer DTL2. In an embodiment, the second planarization film 180 may be formed as an organic layer such as an acryl resin, an epoxy resin, a phenolic resin, a polyamide resin and a polyimide resin.

An light-emitting element layer EML may be arranged on the second planarization film 180 (e.g., disposed directly thereon in the Z-axis direction). In an embodiment, the light-emitting element layer EML may include a plurality of light-emitting elements LEL and a pixel-defining film 190. In an embodiment, each of the light-emitting elements LEL may be, but is not necessarily limited to, an organic light-emitting diode including a pixel electrode 171, an emissive layer 172 and a common electrode 173.

The pixel electrode 171 may be arranged on the second planarization film 180 (e.g., disposed directly thereon in the Z-axis direction). In an embodiment, the pixel electrode 171 may be connected to the second connection electrode CE2 through a third contact hole CT3 penetrating the second planarization film 180.

In an embodiment, in the top-emission structure in which light exits from the emissive layer 172 towards the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

The pixel-defining film 190 may be arranged on the second planarization film 180 to cover the edges of each of the pixel electrodes 171 and to expose central portions of the pixel electrodes 171 to define the light-emitting areas EA. In an embodiment, the pixel-defining film 190 may be formed of an organic layer such as an acryl resin, an epoxy resin, a phenolic resin, a polyamide resin and a polyimide resin.

In each of the first light-emitting area EA1 to the third light-emitting area EA3, the pixel electrode 171, the emissive layer 172 and the common electrode 173 are stacked on one another sequentially (e.g., in the Z-axis direction), so that holes from the pixel electrode 171 and electrons from the common electrode 173 are recombined with each other in the emissive layer 172 to emit light.

The emissive layer 172 may be arranged on the pixel electrode 171 (e.g., in the Z-axis direction). The emissive layer 172 may include an organic material to emit light of a certain color. For example, in an embodiment the emissive layer 172 may include a hole transporting layer, an organic material layer, and an electron transporting layer.

The common electrode 173 may be arranged on the emissive layer 172 (e.g., in the Z-axis direction). The common electrode 173 may be arranged to cover the emissive layer 172. The common electrode 173 may be a common layer formed commonly across the first light-emitting area EA1 to the third light-emitting area EA3. In an embodiment, a capping layer may be formed on the common electrode 173 (e.g., disposed directly thereon in the Z-axis direction).

In an embodiment, in the top-emission organic light-emitting diode, the common electrode 173 may be formed of a transparent conductive material (TCM) such as ITO and IZO that can transmit light, or a semi-transmissive conductive material such as magnesium (Mg), silver (Ag) and an alloy of magnesium (Mg) and silver (Ag). In an embodiment in which the common electrode 173 is formed of a semi-transmissive conductive material, the light extraction efficiency can be increased by using microcavities.

A spacer 191 may be arranged on the pixel-defining film 190 (e.g., directly thereon in the Z-axis direction). The spacer 191 may support a mask during a process of fabricating the emissive layer 172. In an embodiment, the spacer 191 may be formed of an organic layer such as an acryl resin, an epoxy resin, a phenolic resin, a polyamide resin and a polyimide resin.

An encapsulation layer TFE may be arranged on the common electrode 173 (e.g., disposed directly thereon in the Z-axis direction). The encapsulation layer TFE includes at least one inorganic layer to prevent permeation of oxygen or moisture into the light-emitting element layer EML. In addition, the encapsulation layer TFE includes at least one organic layer to protect the light-emitting element layer EML from foreign substances such as dust. For example, in an embodiment the encapsulation layer TFE may include a first inorganic encapsulation layer TFE1, an organic encapsulation layer TFE2 and a second inorganic encapsulation layer TFE3 consecutively stacked (e.g., in the Z-axis direction).

The first inorganic encapsulation film TFE1 may be arranged on the common electrode 173 (e.g., disposed directly thereon in the Z-axis direction), the organic encapsulation film TFE2 may be arranged on the first inorganic encapsulation film TFE1 (e.g., disposed directly thereon in the Z-axis direction), and the second inorganic encapsulation film TFE3 may be arranged on the organic encapsulation film TFE2 (e.g., disposed directly thereon in the Z-axis direction). In an embodiment, the first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another (e.g., in the Z-axis direction). In an embodiment, the organic encapsulation film TFE2 may be an organic film such as an acryl resin, an epoxy resin, a phenolic resin, a polyamide resin, a polyimide resin, etc.

In the example shown in FIG. 6, the third light-emitting area EA3 is larger than the first light-emitting area EA1, and the first light-emitting area EA1 is larger than the second light-emitting area EA2. In an embodiment, the first light-emitting area EA1 may be a red light-emitting area, the second light-emitting area EA2 may be a green light-emitting area, and the third light-emitting area EA3 may be a blue light-emitting area. It should be understood, however, that the relative sizes of the light-emitting areas are not necessarily limited thereto.

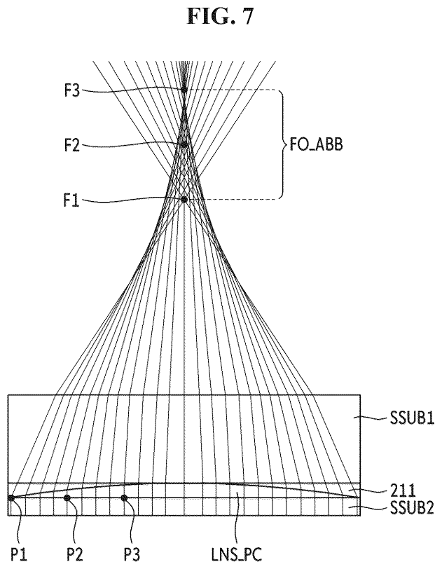

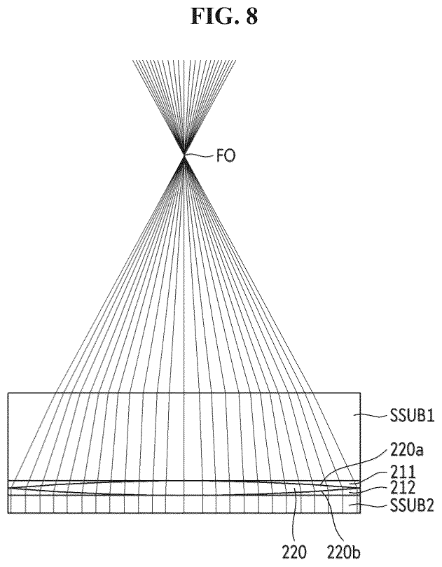

FIGS. 7 and 8 are views for illustrating a focus of a display device according to some embodiments of the present disclosure.

FIG. 7 shows an example of optical paths of an existing display device. FIG. 8 shows an example of optical paths of a display device according to the present disclosure.

Referring to FIG. 7, in an embodiment the existing display device may include a lens LNS_PC and a first resin layer 211 between a first base substrate SSUB1 and a second base substrate SSUB2.

The lower surface of the lens LNS_PC may be in direct contact with the second base substrate SSUB2. In an embodiment, the lower surface of the lens LNS_PC may be formed as a flat surface.

The upper surface of the lens LNS_PC may be formed as a curved surface. The upper surface of the lens LNS_PC may be in direct contact with the first resin layer 211.

In the existing display device according to a comparative embodiment, light passing through a first point P1 of the lens LNS_PC may propagate to a first focus F1. In the existing display device, light passing through a second point P2 of the lens LNS_PC may propagate to a second focus F2. In the existing display device, light passing through a third point P3 of the lens LNS_PC may propagate to a third focus F3. As described above, in the existing display device according to a comparative embodiment, the focus of light passing through the edge of the lens LNS_PC is separated from the focus of light passing through the center of the lens LNS_PC due to spherical aberration, so that the lights passing through the lens LNS_PC do not propagate to a single focus but propagate to a focal range FO_ABB. As a result, 3D images output from the display device may be unclear, or images may be displayed outside the viewing area, causing dizziness to the user.

In contrast, referring to FIG. 8, a display device 10 according to some embodiments of the present disclosure may include a plurality of lenses 220, a first resin layer 211, and a second resin layer 212 between the first base substrate SSUB1 and the second base substrate SSUB2.

Light passing through the second base substrate SSUB2 may be incident on the plurality of lenses 220 from the second resin layer 212 and may be refracted at the second lens surface 220b. Subsequently, light propagating to the first resin layer 211 from the plurality of lenses 220 may be refracted at the first lens surface 220a. By doing so, the spherical aberration that occurs in the existing display devices is corrected, so that light passing through the edges of the lenses 220 and light passing through the center of the lenses 220 all propagate to a single focus FO. As a result, according to an embodiment of the present disclosure, 3D images can become clearer, dizziness felt by a user can be reduced, and 3D crosstalk can be suppressed compared to existing display devices. 3D crosstalk means that different view images appear mixed to the user in a viewing area.

In an embodiment, for lenses having the same focal length, the first curvature of the first lens surface 220a and the second curvature of the second lens surface 220b of FIG. 8 may be reduced compared to the curvature of the lens LNS_PC of FIG. 7. When each of the plurality of lenses 220 has only one lens surface, the lenses 220 have a higher curvature than that of an embodiment of the present disclosure, and thus the light passing through the edge of each of the plurality of lenses 220 was greatly refracted.

In addition, in the existing display device of a comparative embodiment as shown in FIG. 7, since the focus of light passing through the edge of the lens LNS_PC is separated from the focus of light passing through the center of the lens LNS_PC due to spherical aberration, 3D images output from the display device may not be clear, or images may be displayed outside the viewing areas, causing dizziness to the user.

In contrast, according to an embodiment of the present disclosure, since the curvature of the plurality of lenses 220 is reduced, light passing through the edge of each of the plurality of lenses 220 is refracted less and can accurately propagate to the viewing areas. As a result, 3D crosstalk can be suppressed, so that 3D images can become clear compared to existing display devices, and dizziness felt by a user can be reduced.

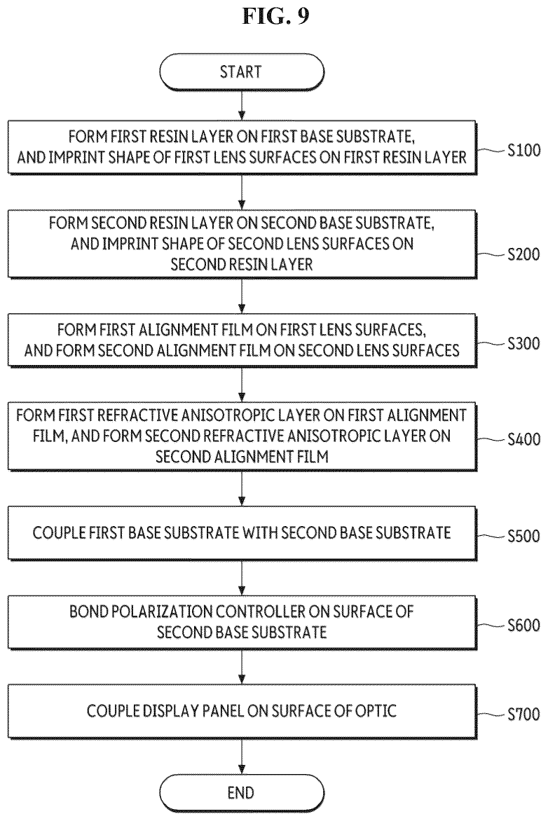

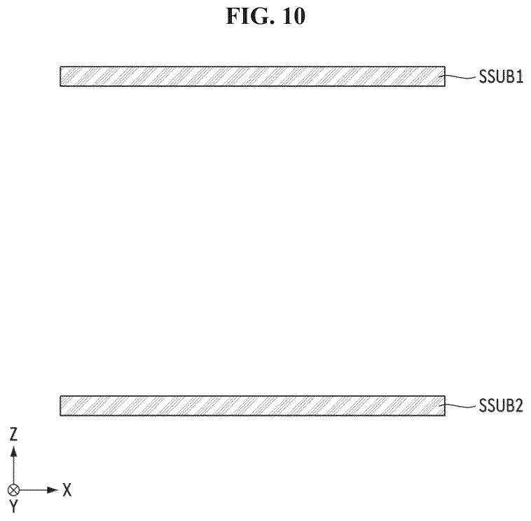

FIG. 9 is a flowchart for illustrating a method for fabricating a display device according to some embodiments of the present disclosure. FIGS. 10 to 18 are views for illustrating a method for fabricating the display device of FIG. 9.

Hereinafter, a method for fabricating a display device according to some embodiments of the present disclosure will be described with reference to FIGS. 9 to 18. The following description will focus on differences and the redundant description may be omitted for economy of explanation.

In an embodiment, a first resin layer 211 is formed on (e.g., formed directly thereon in a direction opposite to the Z-axis direction) a first base substrate SSUB1, and the shape of a first lens surface 220a is imprinted on the first resin layer 211 in step S100 of FIG. 9. In addition, a second resin layer 212 is formed on the second base substrate SSUB2 (e.g., formed directly thereon in the Z-axis direction), and the shape of the second lens surface 220b is imprinted on the second resin layer 212 in step S200 of FIG. 9.

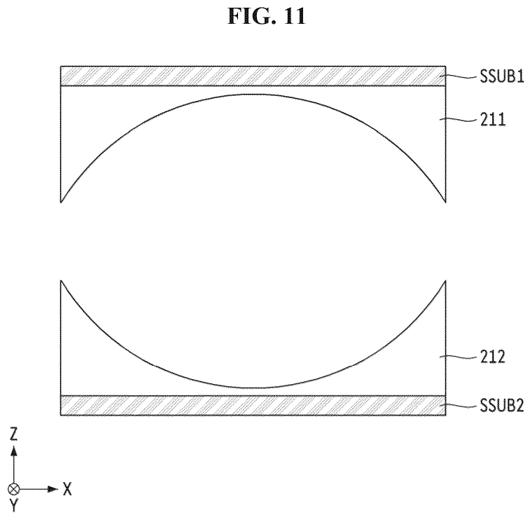

In an embodiment, referring to FIGS. 10 and 11, the first resin layer 211 may be formed on a surface of the first base substrate SSUB1. At this time, the shape of the first lens surface 220a may be imprinted on the first resin layer 211. In the above process, the curvature of the first lens surface 220a and the size of the first lens surface 220a may be determined.

In an embodiment, a second resin layer 212 may be formed on a surface of the second base substrate SSUB2 (e.g., formed directly thereon in the Z-axis direction). The shape of the second lens surface 220b may be imprinted on the second resin layer 212. In the above process, the curvature of the second lens surface 220b and the size of the second lens surface 220b may be determined. In an embodiment, the curvature of the second lens surface 220b may be equal to the curvature of the first lens surface 220a, and the size of the second lens surface 220b may be equal to the size of the first lens surface 220a.

In an embodiment, a first alignment film 213 is then formed on (e.g., formed directly thereon) the first lens surface 220a, and a second alignment film 214 is formed on (e.g., formed directly thereon) the second lens surface 220b in step S300 of FIG. 9.

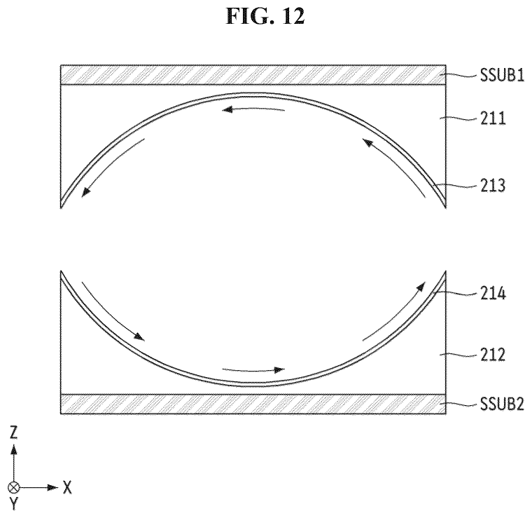

Referring to FIG. 12, the first alignment film 213 may be formed on a surface of the first resin layer 211. For example, in an embodiment a rubbing process using a first rubbing cloth may be performed on the first alignment film 213. For example, a rubbing process may be carried out on the first alignment film 213 in a fourth direction.

In addition, a second alignment film 214 may be formed on a surface of the second resin layer 212. In an embodiment, a rubbing process using a second rubbing cloth that is different from the first rubbing cloth may be performed on the second alignment film 214. For example, the rubbing process may be carried out in the fourth direction or in the opposite direction to the fourth direction on the second alignment film 214.

In an embodiment, a first refractive anisotropic layer 220c1 is then formed on the first alignment film 213, and a second refractive anisotropic layer 220c2 is formed on the second alignment film 214 in step S400 of FIG. 9.

Referring to FIG. 13, the first refractive anisotropic layer 220c1 containing a first refractive anisotropic material may be formed on (e.g., formed directly thereon) the first alignment film 213. At this time, the first refractive anisotropic material may be oriented according to the rubbing process of the first alignment film 213. For example, the first refractive anisotropic material may be oriented in the first direction (e.g., the X-axis direction).

The second refractive anisotropic layer 220c2 containing a second refractive anisotropic material may be formed on (e.g., formed directly thereon) the second alignment film 214. At this time, the second refractive anisotropic material may be oriented according to the rubbing process of the second alignment film 214. When the rubbing process of the second alignment film 214 is performed in the fourth direction or in a direction opposite to the fourth direction, the second refractive anisotropic material may be oriented in the first direction (e.g., the X-axis direction) like the first refractive anisotropic material.

As described above with reference to FIGS. 7 and 8, the curvature of the first lens surfaces 220a and the second lens surfaces 220b according to an embodiment of the present disclosure may be lower than the curvature of lenses LNS_PC of comparative embodiments. As the curvature decreases, the rubbing process can be more easily performed on the edge of the first lens surface 220a and the edge of the second lens surface 220b, so that the orientation of the refractive anisotropic material of the refractive anisotropic layer 220c can be increased. Accordingly, light passing through the edge of the first lens surface 220a and the edge of the second lens surface 220b can accurately propagate to the viewing areas, so that the 3D crosstalk can be reduced.

Subsequently, the first base substrate SSUB1 and the second base substrate SSUB2 are coupled with each other in step S500 of FIG. 9.

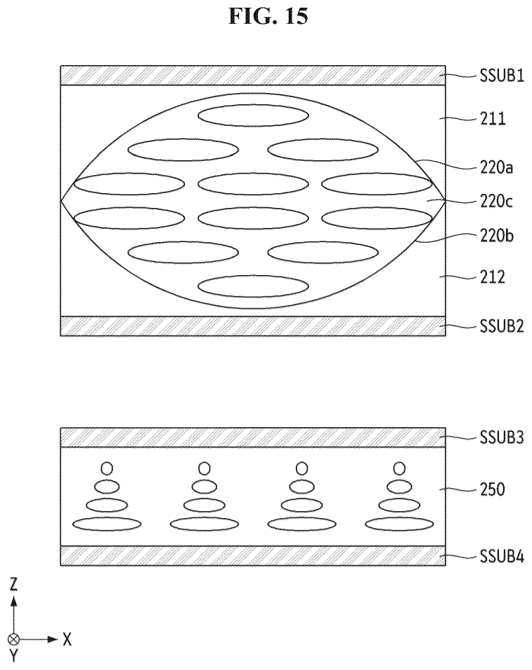

Referring to FIG. 15, the first base substrate SSUB1 and the second base substrate SSUB2 may be coupled with each other such that the edge of the first lens surface 220a and the edge of the second lens surface 220b are in direct contact with each other. The first base substrate SSUB1 may be arranged above the second base substrate SSUB2. For example, in an embodiment the distance between the edge of the first lens surface 220a and the edge of the second lens surface 220b may be less than or equal to 700 nm.

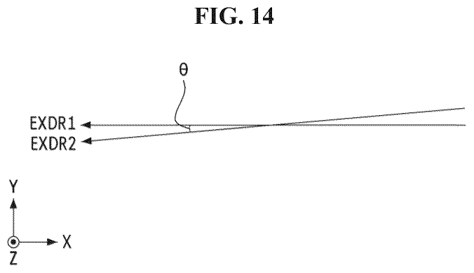

Referring to FIG. 14, a first extension direction EXDR1 of the first lens surface 220a may overlap with a second extension direction EXDR2 of the second lens surface 220b on a plane. For example, in an embodiment the angle θ formed by the first extension direction EXDR1 and the second extension direction EXDR2 may be less than or equal to 0.001°.

In an embodiment, a polarization controller 250 is then bonded to a surface of the second base substrate SSUB2 in step S600 of FIG. 9.

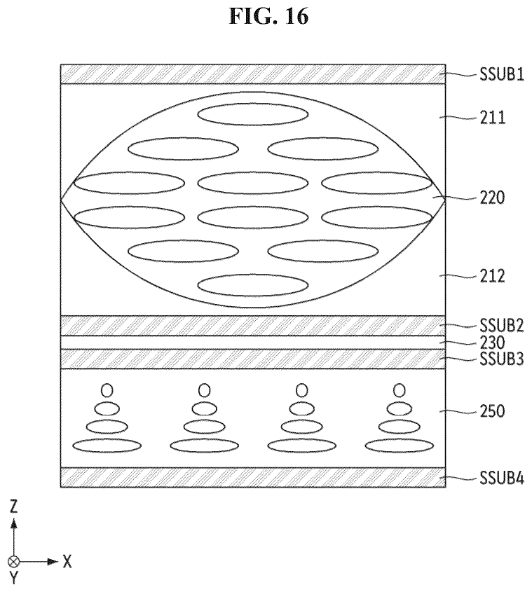

Referring to FIGS. 15 and 16, in an embodiment a coupling portion 230 may be arranged between the lower surface of the second base substrate SSUB2 and the upper surface of the third base substrate SSUB3 (e.g., in the Z-axis direction). The third base substrate SSUB3 may be bonded to the second base substrate SSUB2 through the coupling portion 230.

In an embodiment, a display panel 110 is coupled to a surface of the optic 200 in step S700 of FIG. 9.

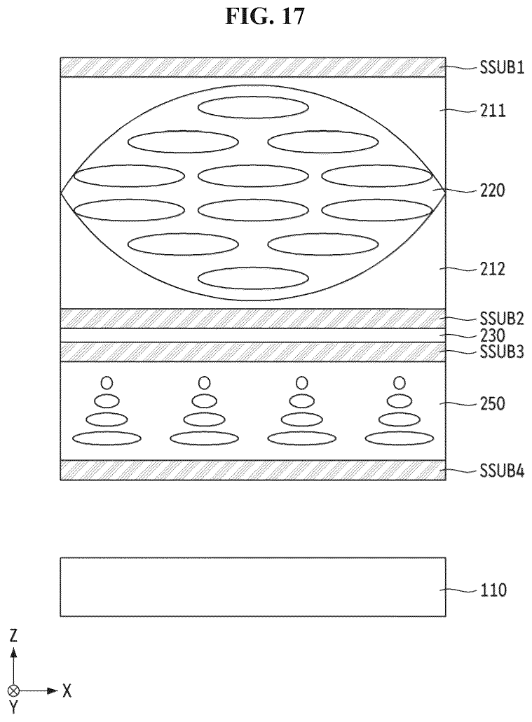

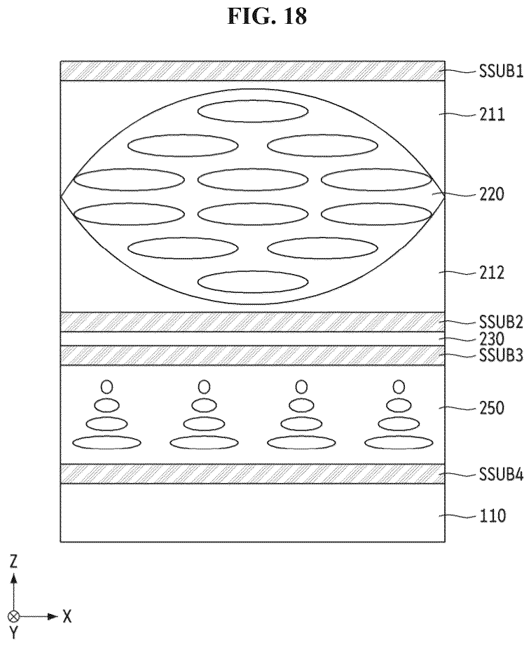

Referring to FIGS. 17 and 18, the fourth base substrate SSUB4 and the display panel 110 may be coupled with each other. The lower surface of the fourth base substrate SSUB4 may be in direct contact with the upper surface of the display panel 110.

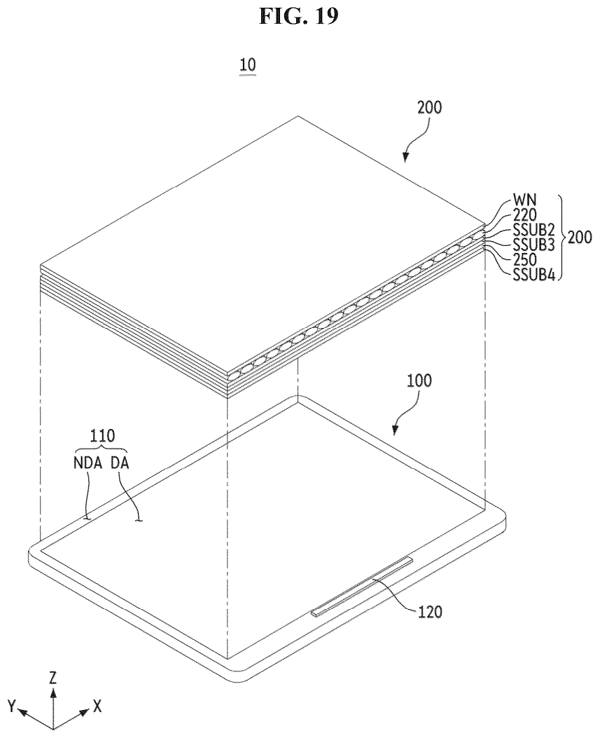

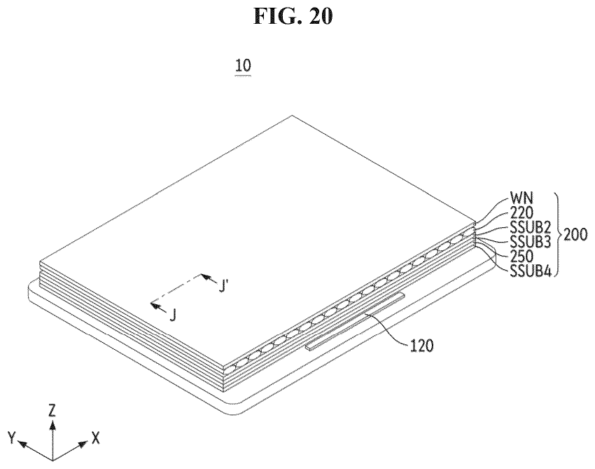

FIG. 19 is an exploded, perspective view of a display device according to some embodiments of the present disclosure. FIG. 20 is a perspective view of the display device of FIG. 19. The following description will focus on differences and the redundant description may be omitted for economy of explanation.

Referring to FIGS. 19 and 20, in an embodiment an optic 200 includes a window WN, a plurality of lenses 220, a second base substrate SSUB2, a third base substrate SSUB3, a polarization controller 250, and a fourth base substrate SSUB4.

Compared to the display device 10 described above with reference to embodiments shown in FIGS. 1 to 8, the display device 10 of an embodiment of FIG. 19 may have the window WN instead of the first base substrate SSUB1. In this embodiment, the thickness and weight of the display device 10 can be reduced.

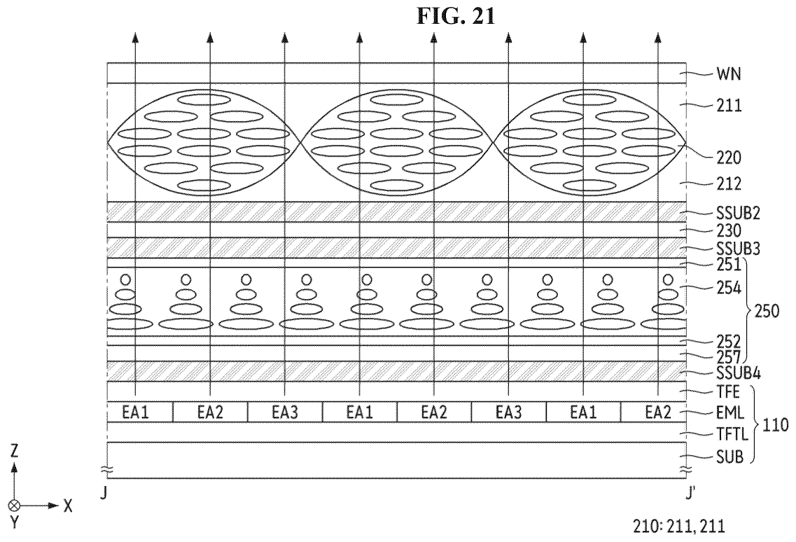

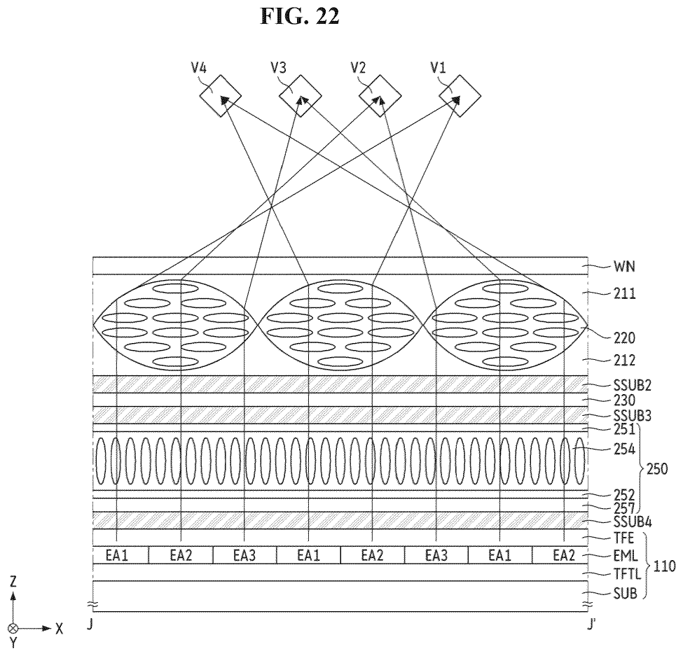

FIG. 21 is a cross-sectional view of the display device, taken along line J-J′ of FIG. 20. FIG. 22 is a cross-sectional view of the display device, taken along line J-J′ of FIG. 20. The following description will focus on differences and the redundant description may be omitted for economy of explanation.

The window WN may be arranged on the first resin layer 211 (e.g., disposed directly thereon in the Z-axis direction). The window WN may include a transparent material that transmits light. For example, the window WN may include polyimide.

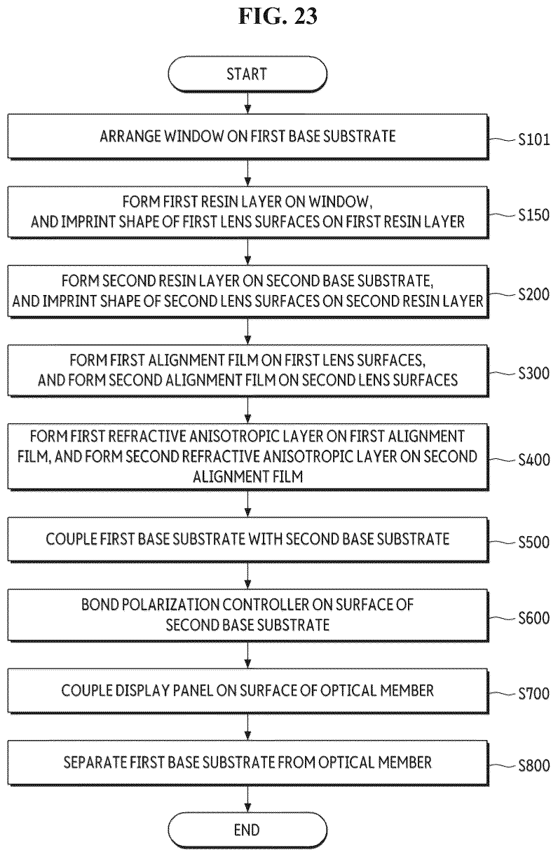

FIG. 23 is a flowchart for illustrating a method for fabricating a display device according to some embodiments of the present disclosure. The following description will focus on differences and the redundant description may be omitted for economy of explanation.

In an embodiment, a window WN is first arranged on the first base substrate SSUB1 in step S101 in FIG. 23.

The window WN may be formed on a surface of the first base substrate SSUB1 (e.g., disposed directly thereon in the Z-axis direction). The window WN may be formed in a shape conforming to the shape of the first base substrate SSUB1 when viewed from the top.

In an embodiment, a first resin layer 211 is then formed on the window WN, and the shape of a first lens surface 220a is imprinted on the first resin layer 211 in step S150 of FIG. 23.

The first resin layer 211 may be formed on the window WN (e.g., formed directly thereon in a direction opposite to the Z-axis direction). A surface of the first resin layer 211 may be in direct contact with the window WN. The shape of the first lens surface 220a may be imprinted on the opposite surface of the first resin layer 211.

In an embodiment, a second resin layer 212 is then formed on the second base substrate SSUB2, and the shape of the second lens surface 220b is imprinted on the second resin layer 212 in step S200 of FIG. 23.

In an embodiment, a first alignment film 213 is then formed on the first lens surface 220a, and a second alignment film 214 is formed on the second lens surface 220b in step S300 of FIG. 23.

In an embodiment, a first refractive anisotropic layer 220c1 is then formed on the first alignment film 213, and a second refractive anisotropic layer 220c2 is formed on the second alignment film 214 in step S400 of FIG. 23.

In an embodiment, the first base substrate SSUB1 and the second base substrate SSUB2 are then coupled with each other in step S500 of FIG. 23.

In an embodiment, a polarization controller 250 is then bonded to a surface of the second base substrate SSUB2 in step S600 of FIG. 23.

In an embodiment, a display panel 110 is then coupled to a surface of the optic 200 in step S700 of FIG. 23.

Steps S200 to S700 of FIG. 23 may be substantially identical to steps S200 to S700 of FIG. 9.

In an embodiment, the first base substrate SSUB1 is then separated from the optic 200 in step S800 of FIG. 23.

The first base substrate SSUB1 may be separated from the optic 200. By separating the first base substrate SSUB1, a window WN may be located at the outermost position of the display device 10. By removing the first base substrate SSUB1, the thickness and weight of the display device 10 can be reduced, thereby relieving the weight burden on the user who uses the display device 10.

### The Electronic Device

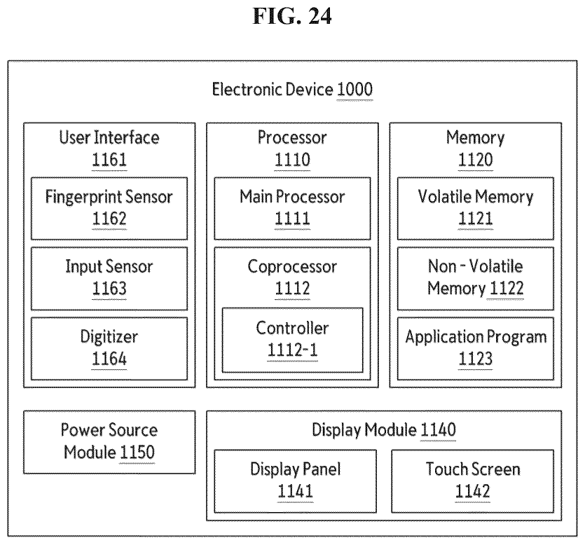

FIG. 24 is a diagram illustrating an electronic device according to an embodiment of the present disclosure. Referring to FIG. 24, the electronic device 1000 according to one embodiment of the present invention may output various information (e.g., images, text, music, etc.) through a display module 1140, which, for example, may correspond to the display device 10 shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 is an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device 10 shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer 1164 may detect an input by a passive pen or transmit and receive data with an active pen or a remote.

At least one of the fingerprint sensor 1162, the input sensor 1163, and the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device 10 shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although non-limiting embodiments of the present disclosure have been described with reference to the accompanying drawings, those skilled in the art would understand that various modifications and alterations may be made without departing from the technical idea or essential features of the present disclosure. Therefore, it should be understood that the above-mentioned embodiments are not limiting but illustrative in all aspects.

What is claimed is:

1. A display device comprising:
a display panel; and
an optic arranged on the display panel,
wherein the optic comprises:
a first base substrate, and a second base substrate arranged between the first base substrate and the display panel;
a plurality of lenses arranged between the first base substrate and the second base substrate, wherein each of the plurality of lenses comprises first lens surfaces that are convex in
a first direction from the second base substrate towards the first base substrate, second lens surfaces that are convex in a direction opposite to the first direction, and a refractive anisotropic layer arranged between the first lens surfaces and the second lens surfaces and comprising a refractive anisotropic material;
a first resin layer arranged between the first base substrate and the first lens surfaces;
a second resin layer arranged between the second base substrate and the second lens surfaces; and
a polarization controller arranged on a surface of the second base substrate, the polarization controller converting a polarization of light incident from the display panel into a first polarized light or a second polarized light.

2. The display device of claim 1, wherein a major axis of the refractive anisotropic material is arranged in a second direction that intersects the first direction, the second direction is an extension direction of the first base substrate and the second base substrate.

3. The display device of claim 2, wherein a refractive index of the first resin layer and a refractive index of the second resin layer are different from a refractive index of the refractive anisotropic layer in a direction of the major axis.

4. The display device of claim 3, wherein the refractive index of the first resin layer is equal to the refractive index of the second resin layer.

5. The display device of claim 1, wherein the first base substrate is in direct contact with the first resin layer, and the second base substrate is in direct contact with the second resin layer.

6. The display device of claim 1, wherein a first curvature of the first lens surfaces is equal to a second curvature of the second lens surfaces.

7. The display device of claim 1, wherein edges of the first lens surfaces are in direct contact with edges of the second lens surfaces.

8. The display device of claim 1, wherein the refractive anisotropic layer comprises:
a first refractive anisotropic layer that is in direct contact with the first lens surfaces and comprises a first refractive anisotropic material, and a second refractive anisotropic layer that is in direct contact with the second lens surfaces and comprises a second refractive anisotropic material, and
wherein the first refractive anisotropic material and the second refractive anisotropic material are not disposed on an interface between the first lens surfaces and the second lens surfaces.

9. The display device of claim 8, wherein the interface is a surface that connects edges of the first lens surfaces with edges of the second lens surfaces.

10. The display device of claim 1, wherein the polarization controller comprises:
a first driving electrode arranged under the second base substrate;
a second driving electrode spaced apart from the first driving electrode;
driving liquid crystals arranged between the first driving electrode and the second driving electrode; and
a polarizer arranged under the second driving electrode and in direct contact with an upper surface of the display panel,
wherein the polarizer transmits light vibrating in a second direction perpendicular to the first direction among light incident from the display panel.

11. The display device of claim 10, wherein in response to a voltage difference between the first driving electrode and the second driving electrode being less than or equal to a predetermined value, a major axis of the driving liquid crystals is aligned in the second direction at a lower portion of the driving liquid crystals, and is aligned in a third direction perpendicular to the second direction towards an upper portion of the driving liquid crystals, and
wherein the third direction is perpendicular to the first direction and the second direction.

12. The display device of claim 11, wherein the major axis of the driving liquid crystals is aligned in the first direction if the voltage difference between the first driving electrode and the second driving electrode is greater than the predetermined value.

13. A method for fabricating a display device comprising a display panel and an optic, the method comprising:
forming a first resin layer on a first base substrate and imprinting a shape of a first lens surface on the first resin layer;
forming a second resin layer on a second base substrate and imprinting a shape of a second lens surface on the second resin layer;
forming a first alignment film on the first lens surface and a second alignment film on the second lens surface;
forming a first refractive index anisotropic layer comprising a first refractive index anisotropic material on the first alignment film and a second refractive index anisotropic layer comprising a second refractive index anisotropic material on the second alignment film;
coupling the first base substrate on the second base substrate such that an edge of the first lens surface and an edge of the second lens surface are in direct contact with each other; and
coupling the display panel on a surface of the second base substrate.

14. The method of claim 13, wherein the forming the first alignment film on the first lens surface and the second alignment film on the second lens surface comprises:
performing a rubbing process in a first direction on the first alignment film using a first rubbing cloth; and
performing a rubbing process in the first direction or in a second direction opposite to the first direction on the second alignment film using a second rubbing cloth.

15. The method of claim 13, further comprising:
forming the optic by bonding a polarization controller on the surface of the second base substrate,
wherein the polarization controller converts a polarization of light incident from the display panel into a first polarized light or a second polarized light.

16. The method of claim 13, wherein a first curvature of the first lens surface is equal to a second curvature of the second lens surface.

17. The method of claim 13, wherein the first refractive index anisotropic layer and the second refractive index anisotropic layer comprise a same material as each other.

18. The method of claim 13, wherein the first refractive index anisotropic layer and the second refractive index anisotropic layer are oriented in a same direction as each other.

19. An electronic device including a display device, the display device comprising:
a display panel; and
an optic arranged on the display panel,
wherein the optic comprises:
a first base substrate, and a second base substrate arranged between the first base substrate and the display panel;
a plurality of lenses arranged between the first base substrate and the second base substrate, wherein each of the plurality of lenses comprises first lens surfaces that are convex in a first direction from the second base substrate towards the first base substrate, second lens surfaces that are convex in a direction opposite to the first direction, and a refractive anisotropic layer arranged between the first lens surfaces and the second lens surfaces and comprising a refractive anisotropic material;
a first resin layer arranged between the first base substrate and the first lens surfaces;
a second resin layer arranged between the second base substrate and the second lens surfaces; and
a polarization controller arranged on a surface of the second base substrate, the polarization controller converting a polarization of light incident from the display panel into a first polarized light or a second polarized light.
